(19) United States
(12) Patent Application Publication
(10) Pub. No.: US 2026/0175402 A1
(43) Pub. Date: Jun. 25, 2026

(54) SUPPORT UNIT AND SUBSTRATE TREATING APPARATUS

(71) Applicant: SEMES CO., LTD., Cheonan-si (KR)

(72) Inventors: Kyung Taek IM, Cheonan-si (KR); Seung Jun LEE, Seoul (KR); Young Un YUN, Asan-si (KR); Jong Gun LEE, Yeosu-si (KR); Yeong An LEE, Cheonan-si (KR); Kyung Sik SHIN, Asan-si (KR); Sung Yong LEE, Yongin-si (KR); Kyoung Don LEE, Cheonan-si (KR)

(21) Appl. No.: 19/411,451

(22) Filed: Dec. 8, 2025

(30) Foreign Application Priority Data
Dec. 20, 2024 (KR) 10-2024-0192202

(51) Int. Cl. B25H 1/00; H10P 72/78

(52) U.S. Cl. CPC B25H 1/0021; H10P 72/78

(57) ABSTRACT

The present disclosure provides a support unit and a substrate treating apparatus. A support unit according to an embodiment of the present disclosure includes a heater assembly including an upper plate and a lower plate formed of metal, and a heater disposed between the upper plate and the lower plate; a cover plate disposed on the upper plate, and formed of ceramic; a sealing member inserted into a cover vacuum hole of the cover plate and an upper vacuum hole of the upper plate, which are formed to be connected to each other, and having a hollow portion communicating with the upper vacuum hole.

### CROSS-REFERENCE TO RELATED APPLICATION(S)

This application claims the benefit of a priority to Korean Patent Application No. 10-2024-0192202 filed on Dec. 20, 2024 in the Korean Intellectual Property Office, the entire disclosure of which is incorporated herein by reference for all purposes.

### BACKGROUND

The present disclosure relates to a support unit supporting a substrate and a substrate treating apparatus including the same.

To manufacture semiconductor devices, various processes such as cleaning, deposition, photolithography, etching, ion implantation, and the like, are performed. Among such processes, a coating process is used to form a liquid film on a substrate.

In general, the coating process is a process of forming a liquid film by applying a treatment solution to a substrate. Before and after forming the liquid film on the substrate, a baking process for baking the substrate is performed.

The baking process is a process of heating the substrate to a process temperature or higher in a closed space, which blows an organic substance on a liquid film to stabilize the liquid film.

A substrate treating apparatus used in this baking process includes a support plate supporting the substrate and a heater installed on the support plate. In this case, a cover plate formed of ceramic is disposed on the support plate to prevent a coating surface of the support plate from peeling off.

Meanwhile, as a high-temperature process which may cause severe warpage of the substrate is gradually introduced, a vacuum-suction role of the support unit for the substrate is becoming more important.

However, due to a difference in coefficients of thermal expansion caused by the different materials of the cover plate and the support plate, which are fixed to each other, a gap between the cover plate and the support plate increases, making it difficult to transmit vacuum pressure to the substrate.

### SUMMARY

The present disclosure has been created to solve the above-described problems, and an aspect of the present disclosure is to provide a support unit and a substrate treating apparatus that prevents a decrease in vacuum suction force for a substrate.

To achieve the object described above, according to an embodiment of the present disclosure, a support unit includes a heater assembly including an upper plate and a lower plate formed of metal, and a heater disposed between the upper plate and the lower plate; a cover plate disposed on the upper plate, and formed of ceramic; and a sealing member inserted into a cover vacuum hole of the cover plate and an upper vacuum hole of the upper plate, which are formed to be connected to each other, and having a hollow portion communicating with the upper vacuum hole.

A screw line is formed in the upper vacuum hole, and the sealing member may be a sealing bolt which is screw-coupled to the upper vacuum hole.

A bolt head of the sealing bolt may be disposed in the cover vacuum hole, a bolt axis of the sealing bolt may be screw-fastened to the upper vacuum hole, and the interior of the cover vacuum hole may be formed larger than the bolt head of the sealing bolt so that the sealing bolt may move horizontally.

A diameter of the cover vacuum hole may be formed to be larger than that of the upper vacuum hole, and an upper edge of the upper vacuum hole may be a first protruding jaw protruding toward the sealing bolt based on an inner wall of the cover vacuum hole, and a lower surface of a lower portion of the bolt head may be disposed to contact an upper surface of the first protruding jaw.

A second protruding jaw is formed to protrude on an inner side surface of the cover vacuum hole, and the bolt head of the sealing bolt may be formed so that an upper portion thereof is larger than a lower portion thereof, so that the upper portion is positioned above the second protruding jaw and the lower portion is positioned next to the second protruding jaw, and a lower surface of an upper portion of the bolt head may be disposed to not contact an upper surface of the second protruding jaw.

An upper portion of the hollow portion of the sealing bolt may have an inner side surface, formed to have a polygonal structure.

The ceramic may include silicon carbide.

According to another aspect of the present disclosure, a substrate treating apparatus may be provided, the substrate treating apparatus including a process chamber having a processing space for a substrate formed therein; and a support unit disposed in the processing space, and supporting and heating the substrate, wherein the support unit includes a heater assembly including an upper plate and a lower plate formed of metal, and a heater disposed between the upper plate and the lower plate; a cover plate disposed on the upper plate, and formed of ceramic; and a sealing member inserted into an upper vacuum hole of the upper plate and a cover vacuum hole of the cover plate, which are formed to be connected to each other, and having a hollow portion communicating with the upper vacuum hole.

According to another aspect of the present disclosure, a substrate treating apparatus may be provided, the substrate treating apparatus including a process chamber having a processing space for a substrate formed therein; and a support unit disposed in the processing space, and supporting and heating the substrate, wherein the support unit includes a heater assembly including an upper plate and a lower plate formed of metal, and a heater disposed between the upper plate and the lower plate; a cover plate disposed on the upper plate, and formed of ceramic; and a sealing member inserted into an upper vacuum hole of the upper plate and a cover vacuum hole of the cover plate, which are formed to be connected to each other, and having a hollow portion communicating with the upper vacuum hole.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional view illustrating a support unit according to the prior art;

FIG. 2 is a diagram illustrating that a cover plate is disposed on the upper plate of the support unit of FIG. 1;

FIG. 3 is an enlarged view illustrating A of FIG. 2;

FIG. 4 is a diagram illustrating a support unit according to an embodiment of the present disclosure;

FIG. 5 is an enlarged view illustrating B of FIG. 4; and

FIG. 6 is a diagram illustrating that a sealing member also moves in accordance with the movement of the upper and lower plates in the support unit of FIG. 5.

### DETAILED DESCRIPTION

Hereinafter, preferred embodiments of the present disclosure will be described in detail so that those skilled in the art could easily practice the present disclosure with reference to the accompanying drawings. However, in describing a preferred embodiment of the present disclosure in detail, if it is determined that a detailed description of a related known function or configuration may unnecessarily obscure the subject matter of the present disclosure, the detailed description will be omitted. In addition, the same reference numerals are used throughout the drawings for parts having similar functions and actions. In addition, in the present specification, terms such as ‘upper,’ ‘upper portion,’ ‘upper surface,’ ‘lower,’ ‘lower portion,’ ‘lower surface,’ ‘side surface,’ and the like are based on the drawings, and in practice, it may be different depending on a direction in which the components are disposed.

In addition, throughout the specification, when a part is said to be ‘connected’ to another part, this is not only when it is ‘directly connected,’ but also when it is ‘indirectly connected’ with other components therebetween. In addition, ‘including’ a certain component means that other components may be further included without excluding other components unless otherwise stated.

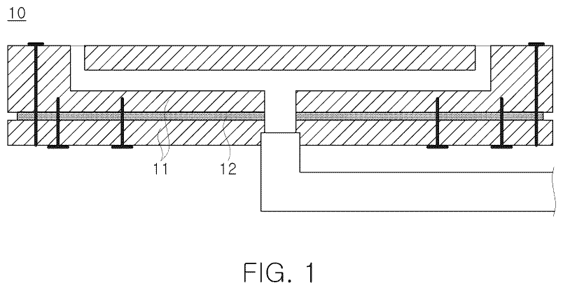

FIG. 1 is a longitudinal cross-sectional view illustrating a support unit according to the prior art.

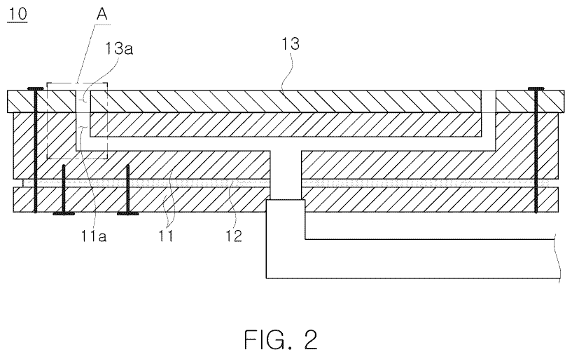

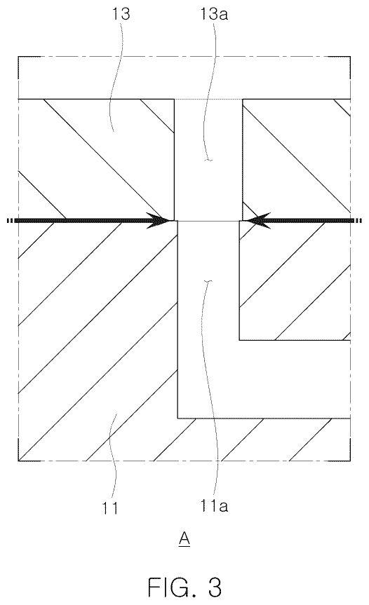

In addition, FIG. 2 is a drawing illustrating that a cover plate is disposed on an upper plate of the support unit of FIG. 1, and FIG. 3 is an enlarged view illustrating A of FIG. 2.

Referring to FIG. 1, a support unit 10 according to the prior art includes a support plate 11 supporting a substrate and a heater 12 heating the substrate.

The support plate 11 may be formed of aluminum as a metal.

A surface of the support plate 11 formed of aluminum is coated with micro-arc oxidation (MAO).

A coating surface of the support plate 11 may be peeled off due to a chemical reaction with a significantly small amount of residual chemical substances and fumes, when a substrate is inserted into a baking chamber, which accompany the substrate. This causes failures and defects due to particles in the substrate treating process.

To prevent this, as shown in FIG. 2, a cover plate 13 formed of ceramic may be disposed on an upper portion of the support plate 11 to cover the entire upper surface of the support plate 11.

Meanwhile, to firmly and stably fix the substrate even when the substrate is bent, a vacuum-suction role of the support unit 10 for the substrate is becoming important.

Vacuum suction of the support unit 10 for the substrate is performed through a cover vacuum hole 13a of the cover plate 13 and a plate vacuum hole 11a of the support plate 11.

However, there may be a difference in coefficients of thermal expansion due to the different materials of the cover plate 13 and the support plate 11. That is, the cover plate 13 formed of ceramic and the support plate 11 formed of aluminum have different coefficients of thermal expansion.

The cover plate 13 and the support plate 11 have a structure fixed by a member such as a fastening bolt, and as a result, a gap between the cover plate 13 and the support plate 11 may increase during thermal expansion of the cover plate 120 and the support plate 11.

As a result, as shown in FIG. 3, air can flow into the gap between the cover plate 13 and the support plate 11, so there is a problem that the vacuum suction of the substrate through the cover vacuum hole 13a and the plate vacuum hole 11a is not performed smoothly.

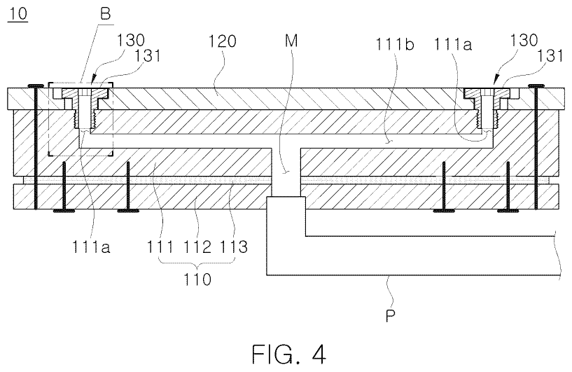

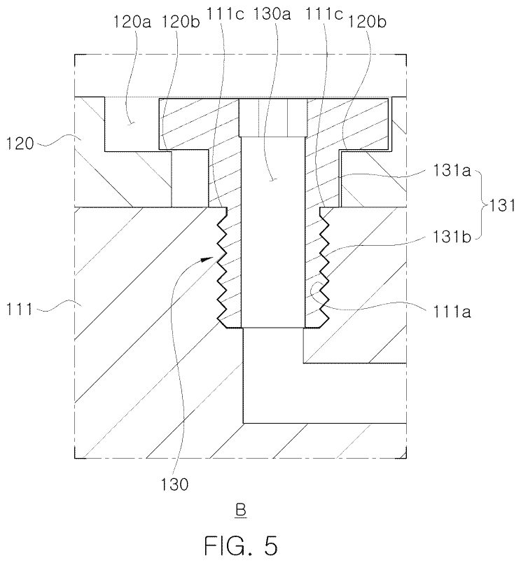

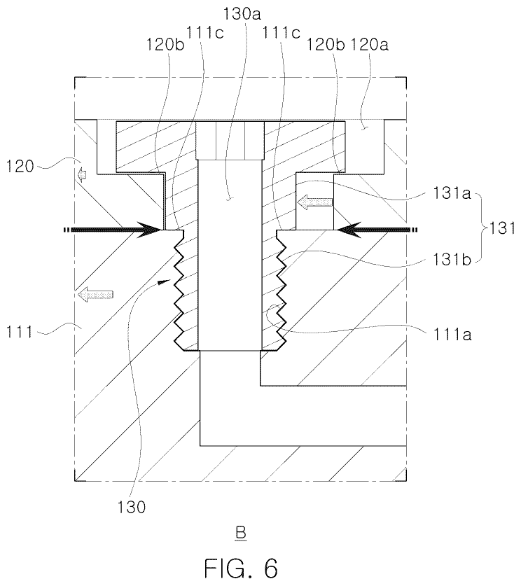

FIG. 4 is a drawing illustrating a support unit according to an embodiment of the present disclosure, FIG. 5 is an enlarged view illustrating B of FIG. 4, and FIG. 6 is a drawing illustrating that a sealing member also moves according to the movement of the upper plate and the lower plate in the support unit of FIG. 5.

Referring to FIGS. 4 to 6, a substrate processing treating apparatus according to an embodiment of the present disclosure includes a process chamber (not shown) and a support unit 100.

Although not shown in the drawing, the process chamber is configured to process substrates therein. To this end, the process chamber is formed with a processing space in which a substrate is processed.

Such a process chamber may be, for example, a baking chamber, and in a photo process, the baking chamber is used for baking to heat the substrate.

In addition, the support unit 100 is disposed in the processing space of the process chamber to support the substrate.

Such a support unit 100 supports the substrate firmly and stably, and may be configured with a lifting pin (not shown) used when receiving or transferring the substrate.

Such a support unit 100 may be configured to support and heat the substrate.

Specifically, the support unit 100 may include a heater assembly 110, a cover plate 120, and a sealing member 130.

The heater assembly 110 may include an upper plate 111, a lower plate 112, and a heater 113.

Here, the upper plate 111 and the lower plate 112 has a plate shape, and the upper plate 111 is disposed thereabove and the lower plate 112 is disposed therebelow.

The heater 113 is disposed between the upper plate 111 and the lower plate 112, and an electric heating wire may be utilized.

More specifically, the upper plate 111 and the lower plate 112 serve as a support structure supporting the substrate as a whole, and at the same time, serve to uniformly transfer heat generated by the heater 113 to the substrate.

To this end, the upper plate 111 and the lower plate 112 may be formed of metal having good thermal conductivity.

As an example, the upper plate 111 and the lower plate 112 may be formed of aluminum, among metals.

As described above, since the upper plate 111 and the lower plate 112 are formed of aluminum, the upper plate 111 and the lower plate 112 have the following advantages. Aluminum has very high thermal conductivity compared to other metals, so aluminum may effectively transfer heat generated from the heater 113 to the substrate. In addition, aluminum is corrosion resistant and can form an oxide layer to prevent corrosion.

The cover plate 120 has a structure disposed on the upper plate 111.

Specifically, the cover plate 120 may be formed to have a size equal to or larger than the upper plate 111 to cover the entire upper surface of the upper plate 111.

Accordingly, when a substrate is inserted into a process chamber, to prevent a significantly small amount of residual chemical substances and fumes, which accompany the substrate, from being in contact with an upper surface of the upper plate 111, the cover plate 120 serves to block the upper surface of the upper plate 111 therefrom. That is, the cover plate 120 covers the entire upper surface of the upper plate 111, thereby ultimately preventing failures and defects caused by particles.

Such a cover plate 120 may be formed of a ceramic material, such a cover plate 120 may have excellent corrosion resistance and wear resistance, and may maintain stability at high temperatures.

As an example, the ceramic may include silicon carbide (SiC).

The silicon carbide has higher corrosion resistance and physical stability compared to other ceramic materials, and also has the advantage of superior heat resistance.

The cover plate 120 may be formed to be thinner than the upper plate 111.

The cover plate 120 is formed of ceramic, so it has excellent corrosion resistance and stability at high temperatures, but has a lower heat transfer rate than metal.

Considering this, in order to secure the advantages of the ceramic described above, such as excellent corrosion resistance and stability at high temperatures, while maintaining the heat transfer rate of the upper plate 111 formed of aluminum to the maximum, the cover plate 120 may have a structure, which is thinner than the upper plate 111.

Meanwhile, a sealing member 130 is installed by being inserted into the cover plate 120 and the upper plate 111.

A cover vacuum hole 120a is formed in the cover plate 120 and an upper vacuum hole 111a is formed in the upper plate 111, and the cover vacuum hole 120a and the upper vacuum hole 111a are formed to be connected to each other in a vertical direction.

In addition, as an example, the upper plate 111 may be formed with a vertical upper vacuum hole 111a and a horizontal vacuum channel 111b connected to the upper vacuum hole 111a. Furthermore, a vertical main channel (M) connected to the vacuum channel 111b may be formed inside the upper plate 111, the heater 113, and the lower plate 112, and the main channel (M) may be connected to a vacuum pump (not shown) by a vacuum pipe (P).

Specifically, a sealing member 130 is installed by being inserted into the cover vacuum hole 120a of the cover plate 120 and the upper vacuum hole 111a of the upper plate 111.

Such a sealing member 130 has a hollow portion 130a communicating with the upper vacuum hole 111a.

Even if a gap is formed between the cover plate 120 and the upper plate 111 as the gap therebetween increases during the thermal expansion, the sealing member 130 configured in this manner may block the gap therebetween and the upper vacuum hole 111a.

Specifically, a screw line is formed in the upper vacuum hole 111a.

In addition, the sealing member 130 may be a sealing bolt 131 which is screw-fastened to the upper vacuum hole 111a.

As described above, the sealing bolt 131 may be screw-fastened to the screw line of the upper vacuum hole 111a, so that an assembly contact surface of an inner surface of the upper vacuum hole 111a and an outer surface of the sealing bolt 131 may have a sealing structure such as a labyrinth line.

Therefore, as shown in FIGS. 5 and 6, even if a gap is formed between the cover plate 120 and the upper plate 111 as the gap therebetween increases during the thermal expansion, air flowing in through this gap may be firmly blocked from flowing in between the sealing bolt 131 and the upper vacuum hole 111a by a screw fastening structure such as a labyrinth line structure.

More specifically, a bolt head 131a of the sealing bolt 131 may be disposed in the cover vacuum hole 120a.

That is, a bolt axis 131b of the sealing bolt 131 may be screw-fastened while being inserted into the upper vacuum hole 111a, and the bolt head 131a of the sealing bolt 131 may have a structure, inserted into the cover vacuum hole 120a.

Here, the interior of the cover vacuum hole 120a may be formed larger than the bolt head 131a of the sealing bolt 131 so that the sealing bolt 131 may move horizontally.

To this end, a diameter of the cover vacuum hole 120a may be formed to be larger than that of the upper vacuum hole 111a.

In addition, an upper edge of the upper vacuum hole 111a may be a first protruding jaw 111c protruding toward the sealing bolt 131 based on an inner wall of the cover vacuum hole 120a, and a lower surface of a lower portion of the bolt head 131a may be disposed to contact an upper surface of the first protruding jaw 111c.

The upper plate 111 and the cover plate 120 have different thermal expansion rates.

That is, since the upper plate 111 is formed of aluminum, which is metal, and the cover plate 120 is formed of ceramic, the upper plate 111 formed of metal has a relatively greater coefficient of thermal expansion than that of the cover plate 120.

When the substrate is heated by the heater 113, the upper plate 111 and the cover plate 120 receive heat while transferring heat from the heater 113 to the substrate and thermally expand.

However, since the upper plate 111 and the cover plate 120 have different thermal expansion rates, the upper plate 111 thermally expands more than the cover plate 120, and when the sealing bolt 131 moves horizontally together with the upper plate 111, the cover plate 120 formed of ceramic may break.

Accordingly, as shown in FIGS. 5 and 6, a diameter of the cover vacuum hole 120a is larger than that of the upper vacuum hole 111a, and the bolt head 131a is in contact with an upper surface of the first protruding jaw 111c, so that even if the upper plate 111 thermally expands more during thermal expansion of the upper plate 111 and the cover plate 120, the cover plate 120 may be prevented from breaking as the sealing bolt 131 may move horizontally on the inside of the cover vacuum hole 120a, while a sealing structure is maintained.

A second protruding jaw 120b may be formed to protrude on an inner side surface of the cover vacuum hole 120a.

A bolt head 131a of the sealing bolt 131 may be formed so that an upper portion thereof is larger than a lower portion thereof, so that the upper portion is positioned above the second protruding jaw 120b and the lower portion is positioned next to the second protruding jaw 120b.

Since an inner surface of the cover vacuum hole 120a and an outer surface of the bolt head 131a, formed to correspond to each other, have a folded structure, rather than a vertical structure, even if a gap is formed between the cover plate 120 and the upper plate 111 as the gap therebetween increases during the thermal expansion, air flowing in through such a gap may be prevented from easily flowing in between the bolt head 131a and the cover vacuum hole 120a.

That is, by increasing the resistance of airflow, the second protruding jaw 120b of the cover vacuum hole 120a may minimize an upward flow of the air flowing in through the gap between the cover vacuum hole 120a and the sealing bolt.

In addition thereto, a lower surface of an upper portion of the bolt head 131a may be disposed to not contact an upper surface of the second protruding jaw 120b. That is, the lower surface of the upper portion of the bolt head 131a may have a structure disposed to be close to, but spaced apart from, the upper surface of the second protruding jaw 120b.

Due thereto, even if the upper plate 111 thermally expands more during the thermal expansion of the upper plate 111 and the cover plate 120, the cover plate 120 may be prevented from breaking, by the bolt head 131a of the sealing bolt 131 that moves horizontally together with the upper plate 111.

Meanwhile, an upper portion of a hollow portion 130a of the sealing bolt 131 may have an inner side surface, formed to have a polygonal structure.

The upper portion of the sealing bolt 131 in which such a polygonal structure is formed is a portion formed so that an assembly tool is fitted to rotate the sealing bolt 131 when the sealing bolt 131 is screw-fastened to the upper vacuum hole 111a.

Accordingly, the sealing bolt 131 has a hollow portion 130a, which is connected to the upper vacuum hole 111a, and may be easily fastened to the upper vacuum hole 111a of the upper plate 111 by an assembly tool.

According to an embodiment of the present disclosure, a support unit and a substrate treating apparatus may be configured to have a sealing member having a hollow portion inserted into a cover vacuum hole of a cover plate and an upper vacuum hole of an upper plate, thereby preventing vacuum suction force for a substrate from being reduced due to air flowing into a gap formed between the cover plate and the support plate.

While exemplary embodiments have been shown and described above, it will be apparent to those skilled in the art that modifications and variations could be made without departing from the scope of the present invention as defined by the appended claims.

What is claimed is:

1. A support unit, comprising:
a heater assembly including an upper plate and a lower plate formed of metal, and a heater disposed between the upper plate and the lower plate;
a cover plate disposed on the upper plate, and formed of ceramic;
a sealing member inserted into a cover vacuum hole of the cover plate and an upper vacuum hole of the upper plate, which are formed to be connected to each other, and having a hollow portion communicating with the upper vacuum hole.

2. The support unit of claim 1, wherein a screw line is formed in the upper vacuum hole, and
the sealing member is a sealing bolt, which is screw-fastened to the upper vacuum hole.

3. The support unit of claim 2, wherein a bolt head of the sealing bolt is disposed in the cover vacuum hole, and a bolt axis of the sealing bolt is screw-fastened to the upper vacuum hole, and
the interior of the cover vacuum hole is formed to be larger than the bolt head of the sealing bolt so that the sealing bolt is movable horizontally.

4. The support unit of claim 3, wherein a diameter of the cover vacuum hole is formed to be larger than that of the upper vacuum hole, and
an upper edge of the upper vacuum hole is a first protruding jaw protruding toward the sealing bolt based on an inner wall of the cover vacuum hole, and a lower surface of a lower portion of the bolt head is disposed to contact an upper surface of the first protruding jaw.

5. The support unit of claim 4, wherein a second protruding jaw is formed to protrude on an inner side surface of the cover vacuum hole, and
a bolt head of the sealing bolt is formed so that an upper portion thereof is larger than a lower portion thereof, so that the upper portion is positioned above the second protruding jaw, and the lower portion is positioned next to the second protruding jaw, and
the lower surface of the upper portion of the bolt head is disposed to not contact the upper surface of the second protruding jaw.

6. The support unit of claim 2, wherein an upper portion of the hollow portion of the sealing bolt has an inner side surface formed to have a polygonal structure.

7. The support unit of claim 1, wherein the ceramic includes silicon carbide.

8. A substrate treating apparatus, comprising:
a process chamber having a processing space for a substrate formed therein; and
a support unit disposed in the processing space, and supporting and heating the substrate,
wherein the support unit includes
a heater assembly including an upper plate and a lower plate formed of metal, and a heater disposed between the upper plate and the lower plate;
a cover plate disposed on the upper plate, and formed of ceramic,
a sealing member inserted into an upper vacuum hole of the upper plate and a cover vacuum hole of the cover plate, which are formed to be connected to each other, and having a hollow portion communicating with the upper vacuum hole.

9. The substrate treating apparatus of claim 8, wherein a screw line is formed in the upper vacuum hole, and
the sealing member is a sealing bolt which is screw-fastened to the upper vacuum hole.

10. The substrate treating apparatus of claim 9, wherein a bolt head of the sealing bolt is disposed in the cover vacuum hole, and a bolt axis of the sealing bolt is screw-fastened to the upper vacuum hole, and
the interior of the cover vacuum hole is formed larger than the bolt head of the sealing bolt so that the sealing bolt is movable horizontally.

11. The substrate treating apparatus of claim 10, wherein a diameter of the cover vacuum hole is formed larger than that of the upper vacuum hole, and
an upper edge of the upper vacuum hole is a first protruding jaw protruding toward the sealing bolt based on an inner wall of the cover vacuum hole, and a lower surface of a lower portion of the bolt head is disposed to contact an upper surface of the first protruding jaw.

12. The substrate treating apparatus of claim 11, wherein a second protruding jaw is formed to protrude on an inner side surface of the cover vacuum hole,
the bolt head of the sealing bolt is formed so that an upper potion thereof is larger than a lower portion thereof, so that the upper portion is positioned above the second protruding jaw and the lower portion is positioned next to the second protruding jaw, and
the lower surface of the upper portion of the bolt head is disposed to not contact the upper surface of the second protruding jaw.

13. The substrate treating apparatus of claim 9, wherein an upper portion of the hollow portion of the sealing bolt has an inner surface formed to have a polygonal structure.

14. The substrate treating apparatus of claim 8, wherein the ceramic includes silicon carbide.

15. A substrate treating apparatus, comprising:
a process chamber having a processing space for a substrate formed therein; and
a support unit disposed in the processing space, and supporting and heating the substrate,
wherein the support unit includes
a heater assembly including an upper plate and a lower plate formed of metal, and a heater disposed between the upper plate and the lower plate;
a cover plate disposed on the upper plate, and formed of ceramic; and
a sealing member inserted into an upper vacuum hole of the upper plate and a cover vacuum hole of the cover plate, which are formed to be connected to each other, and having a hollow portion communicating with the upper vacuum hole,
wherein the cover plate includes silicon carbide, and covers the entire upper surface of the upper plate and is thinner than the upper plate.

16. The substrate treating apparatus of claim 15, wherein a screw line is formed in the upper vacuum hole, and
the sealing member is a sealing bolt, which is screw-fastened to the upper vacuum hole.

17. The substrate treating apparatus of claim 16, wherein a bolt head of the sealing bolt is disposed in the cover vacuum hole, and a bolt axis of the sealing bolt is screw-fastened to the upper vacuum hole, and
the interior of the cover vacuum hole is formed to be larger than the bolt head of the sealing bolt so that the sealing bolt is movable horizontally.

18. The substrate treating apparatus of claim 17, wherein a diameter of the cover vacuum hole is formed larger than that of the upper vacuum hole, and
an upper edge of the upper vacuum hole is a first protruding jaw protruding toward the sealing bolt based on an inner wall of the cover vacuum hole, and a lower surface of a lower portion of the bolt head is disposed to contact an upper surface of the first protruding jaw.

19. The substrate treating apparatus of claim 18, wherein a second protruding jaw is formed on an inner side surface of the cover vacuum hole,
the bolt head of the sealing bolt is formed so that an upper portion thereof is larger than a lower portion thereof, so that the upper portion is positioned above the second protruding jaw and the lower portion is positioned next to the second protruding jaw, and
a lower surface of the upper portion of the bolt head is disposed to not contact an upper surface of the second protruding jaw.

20. The substrate treating apparatus of claim 16, wherein an upper portion of the hollow portion of the sealing bolt has an inner surface formed to have a polygonal structure.
